(19) United States
(12) Patent Application Publication
(10) Pub. No.: US 2022/0240404 A1
(43) Pub. Date: Jul. 28, 2022

(54) ELECTRONIC APPARATUS

(71) Applicant: Mitsubishi Electric Corporation, Tokyo (JP)

(72) Inventor: Takashi YAMAUCHI, Tokyo (JP)

(73) Assignee: Mitsubishi Electric Corporation, Tokyo (JP)

(21) Appl. No.: 17/614,910

(22) PCT Filed: Jul. 4, 2019
(86) PCT No.: PCT/JP2019/026664

§ 371 Date: Nov. 29, 2021

(51) Int. Cl. H05K 7/12; H02G 3/02

(52) U.S. Cl. CPC H05K 7/12; H02G 3/02

(57) ABSTRACT

An electronic apparatus includes a chassis and a substrate arranged to face each other, a cable disposed between the chassis and the substrate and having an extra length, and a plurality of clampers formed on the chassis and clamping the cable. The plurality of dampers includes a second damper fixedly clamping the cable and a third clamper movably clamping the cable. The cable is fixed to the chassis by the second damper, and the third damper limits a movable direction and a movable range of the cable in extra length processing of the cable.

### TECHNICAL FIELD

The present invention relates to an electronic apparatus.

### BACKGROUND ART

Conventionally, a technique of fixing a cable in a back surface portion of a display device using a so-called “hook-and-loop fastener” has been developed (see, for example, Patent Literature 1).

### CITATION LIST

### Patent Literatures

Patent Literature 1: JP 2014-153534 A

### SUMMARY OF INVENTION

### Technical Problem

When an electronic apparatus is assembled, work (hereinafter referred to as “connection work”) of connecting a cable to a terminal in the electronic apparatus is performed. From the viewpoint of facilitating the connection work, it is preferable to use a cable having a so-called “extra length”. However, in a case where a cable having an extra length is used, when the cable is connected to the terminal, a part of the cable may protrude out of a predetermined region. In this case, from the viewpoint of avoiding the protruding portion from being caught by another member, the work of pushing the protruding portion into the predetermined region is required. Hereinafter, this work is referred to as “extra length processing”.

Here, although not described or suggested in Patent Literature 1, it is conceivable to use the fixing method described in Patent Literature 1 (hereinafter, referred to as a “conventional fixing method”) for fixing a cable inside an electronic apparatus. However, in the conventional fixing method, the extra length processing is not taken into consideration. For this reason, when the cable is connected to the terminal, there is a problem that the extra length processing is not performed, and a part of the cable may remain out of a predetermined region. In addition, even if the extra length processing is performed, after the protruding portion is pushed into the predetermined region, a so-called “return” occurs, so that the shape of the cable may return to the shape before being pushed in. As a result, there is a problem that the pushed-in portion may protrude out of the predetermined region again.

The present invention has been made to solve the above problem, and an object thereof is to provide an electronic apparatus having a structure for extra length processing.

### Solution to Problem

An electronic apparatus of the present invention includes: a chassis and a substrate arranged to face each other; a cable disposed between the chassis and the substrate and having an extra length; and a plurality of dampers formed on the chassis and clamping the cable, in which the plurality of dampers includes a second damper fixedly clamping the cable and a third damper movably clamping the cable, the cable is fixed to the chassis by the second clamper, and the third damper limits a movable direction and a movable range of the cable in extra length processing of the cable.

### Advantageous Effects of Invention

According to the present invention, with the above configuration, it is possible to obtain an electronic apparatus having a structure for extra length processing.

### BRIEF DESCRIPTION OF DRAWINGS

FIG. 1 is an exploded perspective view illustrating a main part of an electronic apparatus according to a first embodiment.

FIG. 2 is an exploded perspective view illustrating a part of a chassis, a part of a cable, and a part of a substrate in the electronic apparatus according to the first embodiment.

FIG. 3 is a plan view illustrating a part of a chassis and a part of a cable in the electronic apparatus according to the first embodiment, and is a plan view illustrating a state in which a part of a substrate is seen through.

FIG. 4 is a cross-sectional view taken along line A-A′ illustrated in FIG. 3.

FIG. 5 is a cross-sectional view taken along line B-B′ illustrated in FIG. 3.

FIG. 6 is a cross-sectional view taken along line C-C′ illustrated in FIG. 3.

FIG. 7A is an explanatory view illustrating an example of a state after a wiring work is performed and before a connection work is performed.

FIG. 7B is an explanatory view illustrating an example of the connection work.

FIG. 7C is an explanatory view illustrating an example of extra length processing.

FIG. 7D is an explanatory view illustrating an example of a state after the extra length processing is performed.

FIG. 8 is an explanatory view illustrating an example of a state in which a plurality of cables is in contact with a protrusion.

### DESCRIPTION OF EMBODIMENTS

Hereinafter, in order to explain this invention in more detail, a mode for carrying out this invention will be described with reference to the accompanying drawings.

### First Embodiment

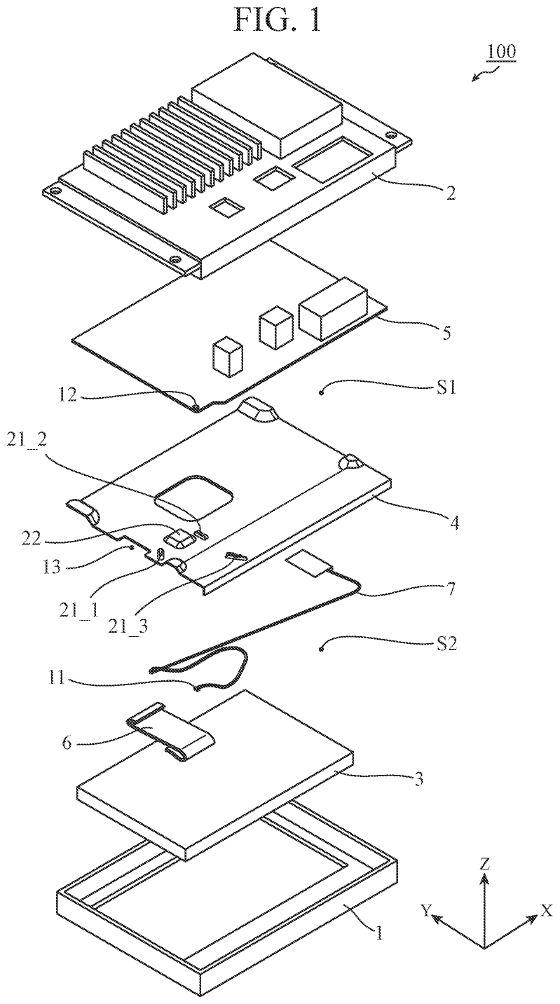

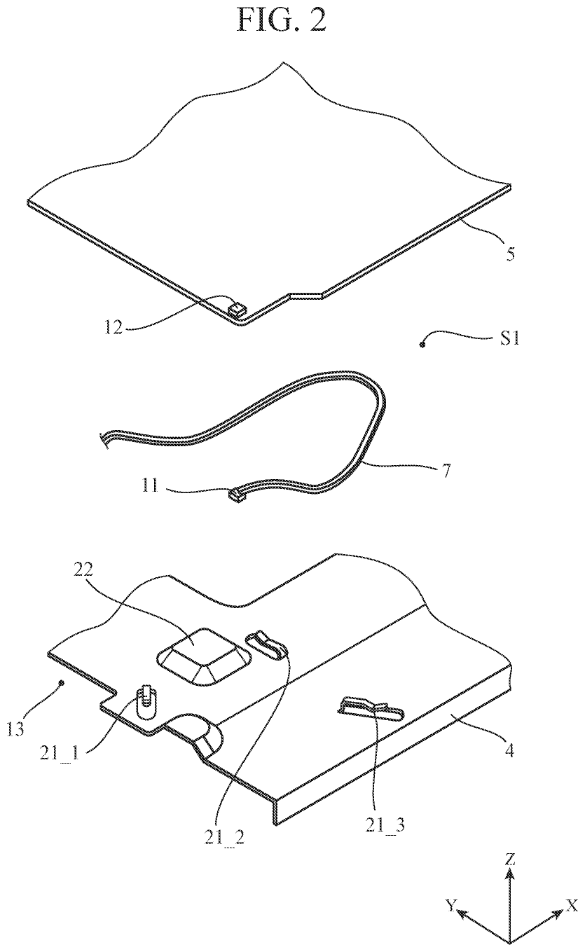

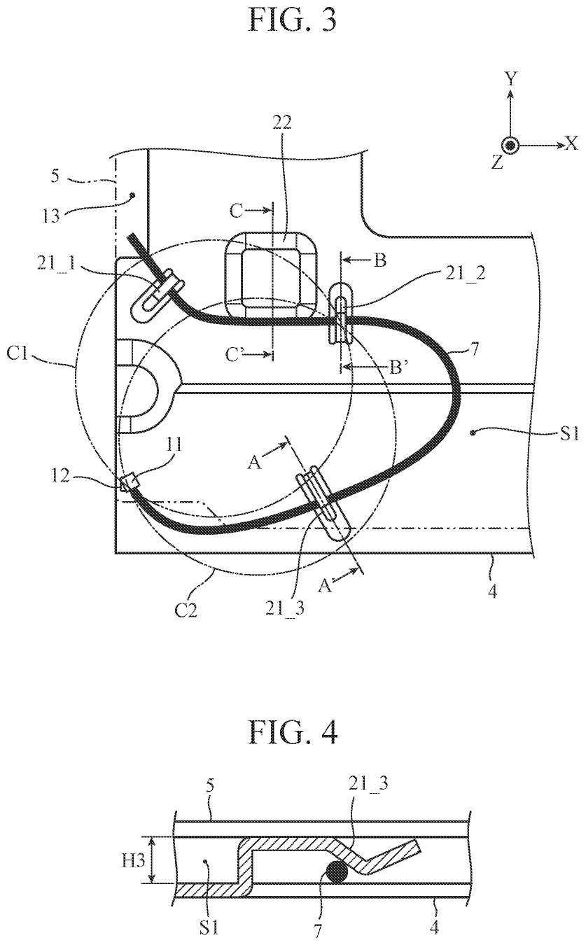

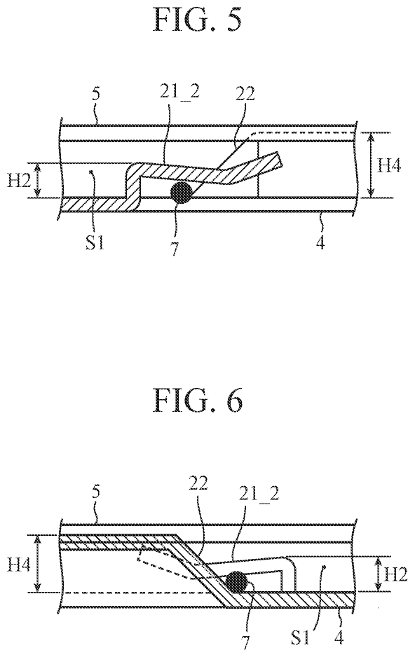

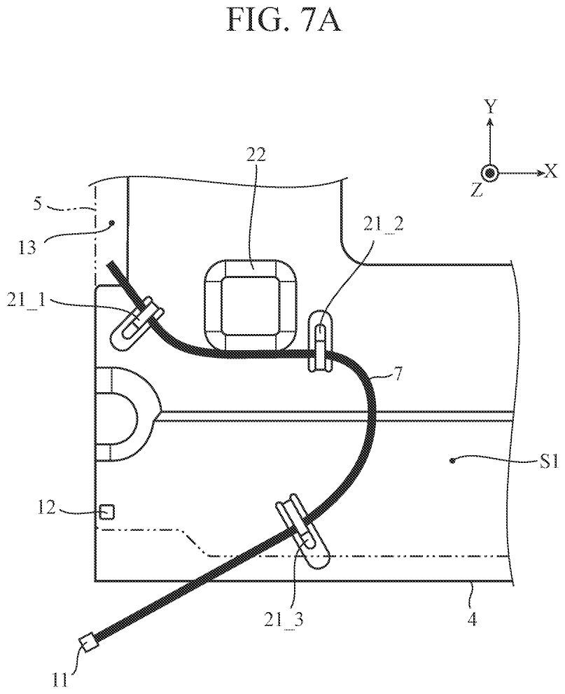

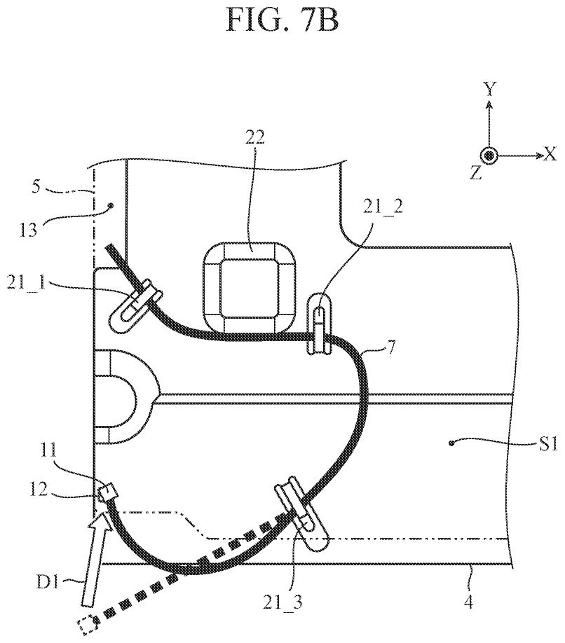

FIG. 1 is an exploded perspective view illustrating a main part of an electronic apparatus according to a first embodiment. FIG. 2 is an exploded perspective view illustrating a part of a chassis, a part of a cable, and a part of a substrate in the electronic apparatus according to the first embodiment. FIG. 3 is a plan view illustrating a part of a chassis and a part of a cable in the electronic apparatus according to the first embodiment, and is a plan view illustrating a state in which a part of a substrate is seen through. FIG. 4 is a cross-sectional view taken along line A-A′ illustrated in FIG. 3. FIG. 5 is a cross-sectional view taken along line B-B′ illustrated in FIG. 3. FIG. 6 is a cross-sectional view taken along line C-C′ illustrated in FIG. 3. The electronic apparatus according to the first embodiment will be described with reference to FIGS. 1 to 6.

An electronic apparatus 100 includes, for example, a display device for an in-vehicle information device. That is, as illustrated in FIG. 1, a liquid crystal module 3, a substantially plate-shaped chassis 4, and a control substrate 5 are sequentially arranged between a front panel 1 and a rear cover 2. In other words, the chassis 4 is disposed between the liquid crystal module 3 and the substrate 5. The liquid crystal module 3 and the chassis 4 are arranged to face each other. The chassis 4 and the substrate 5 are arranged to face each other. The display surface of the liquid crystal module 3 is exposed to the outside of the electronic apparatus 100 through the opening of front panel 1.

The liquid crystal module 3 and the substrate 5 are electrically connected by a flat cable 6. Further, the liquid crystal module 3 and the substrate 5 are electrically connected by a cable 7. Each of the flat cable 6 and the cable 7 is wired so as to avoid the chassis 4 inside the electronic apparatus 100. The front panel 1, the rear cover 2, the liquid crystal module 3, the chassis 4, the substrate 5, the flat cable 6, and the cable 7 constitute a main part of the electronic apparatus 100.

One end portion (hereinafter, referred to as a “first end portion”) of the cable 7 is electrically connected to the substrate 5. More specifically, a connector 11 is provided at the first end portion of the cable 7, a terminal 12 is provided on the substrate 5, and the connector 11 is connected to the terminal 12. Here, a connection portion (not illustrated) between the connector 11 and the terminal 12 has a cylindrical shape. Thus, the connector 11 is rotatable with respect to the terminal 12 in a state of being connected to the terminal 12.

The other end portion (hereinafter, referred to as a “second end portion”.) of the cable 7 is electrically connected to the liquid crystal module 3. For this reason, while the substantially half portion (hereinafter, referred to as a “first half portion”) including the first end portion of the cable 7 is disposed in a space portion (hereinafter, referred to as a “first space portion”) S1 between the chassis 4 and the substrate 5, the substantially half portion (hereinafter, referred to as a “second half portion”) including the second end portion of the cable 7 is disposed in a space portion (hereinafter, referred to as a “second space portion”) S2 between the liquid crystal module 3 and the chassis 4. As described above, at least a part of the cable 7 is disposed between the chassis 4 and the substrate 5.

The cable 7 is pulled out from the second space portion S2 to the first space portion S1 through a notch-shaped recess formed on the chassis 4 (13 in the drawing). Hereinafter, a portion from which the cable 7 is pulled out is referred to as a “pull-out portion”.

Hereinafter, among the directions along the plate surface of the chassis 4, a direction along a virtual straight line passing through the arrangement position of the terminal 12 and the arrangement position of the pull-out portion 13 is referred to as a “second direction” or a “Y direction”. In the drawing, the Y axis indicates a virtual axis along the Y direction. Among the directions along the plate surface of the chassis 4, a direction orthogonal to the Y direction is referred to as a “first direction” or an “X direction”. In the drawing, the X axis indicates a virtual axis along the X direction. Further, a direction orthogonal to the plate surface of the chassis 4, that is, a direction orthogonal to the X direction and the Y direction is referred to as a “Z direction”. In the drawing, the Z axis indicates a virtual axis along the Z direction.

In the example illustrated in FIGS. 1 to 6, the chassis 4 has a substantially rectangular shape. Therefore, the chassis 4 has two short side portions and two long side portions. Here, the terminal 12 and the pull-out portion 13 are arranged at positions corresponding to one of the two short side portions. Accordingly, the Y direction is set to a direction along each of the two short side portions. The X direction is set to a direction along each of the two long side portions.

The chassis 4 is made of sheet metal, for example. A plurality of dampers 21 is formed by cutting and raising the sheet metal and step bending. More specifically, a first damper 21_1, a second damper 21_2, and a third damper 21_3 are formed. The first half portion of the cable 7 is clamped by the individual clampers 21.

As illustrated in FIG. 3, the arrangement position of the terminal 12 with respect to the X direction is set at a position equivalent to the arrangement position of the pull-out portion 13 with respect to the X direction. The arrangement position of the second clamper 21_2 with respect to the X direction is set at a position equivalent to the arrangement position of the third damper 21_3 with respect to the X direction. The arrangement positions of the second damper 21_2 and the third clamper 21_3 with respect to the X direction are set to positions different from the arrangement positions of the terminal 12 and the pull-out portion 13 with respect to the X direction. The arrangement position of the first clamper 21_1 with respect to the X direction is set at a position between the arrangement positions of the terminal 12 and the pull-out portion 13 with respect to the X direction and the arrangement positions of the second damper 21_2 and the third damper 21_3 with respect to the X direction.

Hereinafter, in the X direction, a direction from the arrangement positions of the terminal 12 and the pull-out portion 13 toward the arrangement positions of the second damper 21_2 and the third damper 21_3 is referred to as a “positive direction”. Further, in the X direction, a direction from the arrangement positions of the second damper 21_2 and the third damper 21_3 to the arrangement positions of the terminal 12 and the pull-out portion 13 is referred to as a “negative direction”.

As illustrated in FIG. 3, the arrangement position of the terminal 12 with respect to the Y direction is set at a position different from the arrangement position of the pull-out portion 13 with respect to the Y direction. The arrangement position of the third clamper 21_3 with respect to the Y direction is set at a position equivalent to the arrangement position of the terminal 12 with respect to the Y direction. The arrangement position of the second damper 21_2 with respect to the Y direction is set at a position equivalent to the arrangement position of the first clamper 21_1 with respect to the Y direction. The arrangement positions of the first damper 21_1 and the second damper 21_2 with respect to the Y direction are set at positions between the arrangement positions of the terminal 12 and the third clamper 21_3 with respect to the Y direction and the arrangement position of the pull-out portion 13 with respect to the Y direction.

Hereinafter, in the Y direction, a direction from the arrangement position of the terminal 12 toward the arrangement position of the pull-out portion 13, that is, a direction from the arrangement position of the third damper 21_3 toward the arrangement position of the second damper 21_2 is referred to as a “positive direction”. Further, in the Y direction, a direction from the arrangement position of the pull-out portion 13 toward the arrangement position of the terminal 12, that is, a direction from the arrangement position of the second damper 21_2 toward the arrangement position of the third damper 21_3 is referred to as a “negative direction”.

The opening direction of the first damper 21_1 is set to the negative direction with respect to the X direction and to the negative direction with respect to the Y direction. More specifically, the opening direction of the first damper 21_1 is set to a direction inclined by 45 degrees with respect to each of the X direction and the Y direction. The opening direction of the second damper 21_2 is set to the positive direction with respect to the Y direction. The opening direction of the third clamper 21_3 is set to the positive direction with respect to the X direction and to the negative direction with respect to the Y direction.

That is, the opening direction (positive direction) of the second damper 21_2 with respect to the Y direction is set to a direction opposite to the opening direction (negative direction) of the first damper 21_1 with respect to the Y direction, and is set to a direction opposite to the opening direction (negative direction) of the third clamper 21_3 with respect to the Y direction. In other words, the opening directions of the plurality of dampers 21_1, 21_2, and 21_3 with respect to the Y direction are set to alternately reverse directions (negative direction→positive direction→negative direction).

Hereinafter, a length L of a portion of the cable 7 disposed in the first space portion S1, that is, the length L of the first half portion of the cable 7 is referred to as a “wiring length”. Each of C1 and C2 in FIG. 3 indicates a virtual circle passing through the arrangement position of the terminal 12 and the arrangement position of the second damper 21_2 and having a circumferential length corresponding to the wiring length L (more specifically, a circumferential length equivalent to the wiring length L). The first damper 21_1 is disposed inside one circle C1 out of the two circles C1 and C2. On the other hand, the third clamper 21_3 is disposed inside the other circle C2 of the two circles C1 and C2.

A height H3 (see FIG. 4) of a cut-and-raised portion (hereinafter, referred to as a “cut-and-raised portion”) in the third damper 21_3 is set to a value larger than those of a height H1 (not shown) of a cut-and-raised portion in the first clamper 21_1 and a height H2 (see FIGS. 5 and 6) of a cut-and-raised portion in the second damper 21_2. In other words, the height H1 of the cut-and-raised portion in the first damper 21_1 and the height H2 of the cut-and-raised portion in the second damper 21_2 are set to values smaller than that of the height H3 of the cut-and-raised portion in the third clamper 21_3. Therefore, the first half portion of the cable 7 is fixedly clamped by each of the first damper 21_1 and the second clamper 21_2, and is movably clamped by the third damper 21_3.

As described above, the chassis 4 is made of sheet metal, for example. A protrusion 22 having a drawing shape is formed by drawing or the like on the sheet metal. The protrusion 22 is disposed between the first damper 21_1 and the second damper 21_2. The height H4 of the protrusion 22 is set to a value larger than that of the height H2 of the cut-and-raised portion in the second damper 21_2 (see FIGS. 5 and 6). In addition, the height H4 of the protrusion 22 is set to a value larger than that of the height H1 of the cut-and-raised portion in the first damper 21_1. A portion of the cable 7 between a portion clamped by the first damper 21_1 and a portion clamped by the second clamper 21_2 is in contact with the protrusion 22 (see FIGS. 5 and 6).

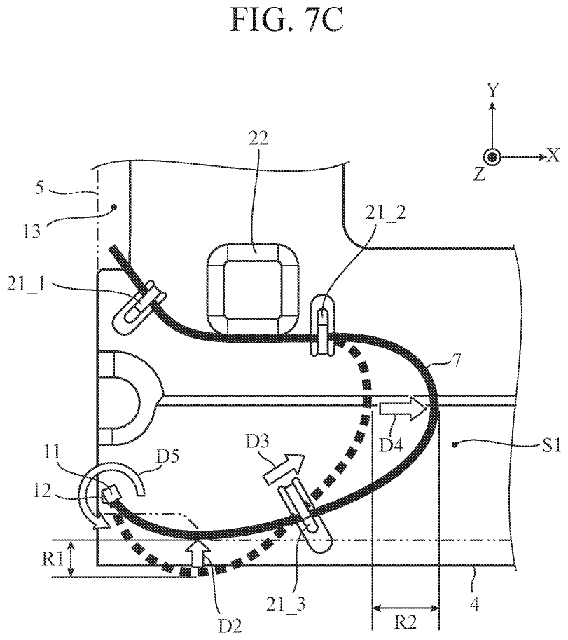

Next, with reference to FIG. 7, a method of assembling the electronic apparatus 100 will be described focusing on the connection work and extra length processing. Furthermore, effects of the structure of the electronic apparatus 100 will be described.

First, in a state where the first half portion of the cable 7 is pulled out from the second space portion S2 to the first space portion S1 through the pull-out portion 13, the worker performs work (hereinafter, referred to as “wiring work”) of sequentially hooking the first half portion of the cable 7 to the first damper 21_1, the second damper 21_2, and the third clamper 21_3. As a result, as illustrated in FIG. 7A, the first half portion of the cable 7 is clamped by each of the first clamper 21_1, the second damper 21_2, and the third damper 21_3. In addition, the connector 11 is guided to a position near the arrangement position of the terminal 12.

Here, as described above, the opening directions of the plurality of dampers 21_1, 21_2, and 21_3 with respect to the Y direction are set to alternately reverse directions (negative direction→positive direction→negative direction). As a result, when the worker performs the wiring work, the movement of the hand of the worker can be made smooth. That is, the moving line of the hand of the worker can be a wavy smooth line. As a result, workability of wiring work can be improved.

Next, as illustrated in FIG. 7B, the worker performs work of guiding the connector 11 to the arrangement position of the terminal 12 and work of connecting the connector 11 to the terminal 12. That is, the worker performs the connection work. D1 in FIG. 7B illustrates an example of the moving direction of the connector 11 in the connection work. At this time, the worker can easily guide the connector 11 to the arrangement position of the terminal 12 with the extra length of the cable 7. That is, the connection work can be facilitated.

However, when the connection work is performed, a part of the cable 7 protrudes to the region outside the chassis 4 due to the extra length of the cable 7 (see FIG. 7B). Then, as illustrated in FIG. 7C, the worker then performs a work of pushing the protruding portion into the region in the chassis 4. That is, the worker performs extra length processing. FIG. 7D illustrates an example of a state after the extra length processing is performed. As illustrated in FIG. 7D, the shape of the first half portion of the cable 7 after the extra length processing is performed is substantially U-shaped.

Here, D2 in FIG. 7C illustrates an example of a direction in which the cable 7 is pushed. D3 and D4 in FIG. 7C illustrate examples of the moving direction of the cable 7 when the cable 7 is pushed. R1 and R2 in FIG. 7C indicate examples of the deformation range of the cable 7 when the cable 7 is pushed. D5 in FIG. 7C indicates a rotation direction of the connector 11 when the cable 7 is pushed.

That is, as described above, the connection portion between the connector 11 and the terminal 12 is configured to be rotatable. As a result, as illustrated in FIG. 7C, when the cable 7 is pushed in by the extra length processing, the connector 11 rotates with respect to the terminal 12 (see D5 in FIG. 7C). As a result, a mechanical load applied to the first end portion of the connector 11 can be reduced as compared with a case where the connection portion between the connector 11 and the terminal 12 is configured to be non-rotatable.

Next, another effect of the structure of the electronic apparatus 100 will be described with reference to FIGS. 3 to 8.

Firstly, as shown in FIG. 3, the arrangement position of the second damper 21_2 with respect to the X direction is set at a position different from the arrangement position of the terminal 12 with respect to the X direction, and is set at a position equivalent to the arrangement position of the third damper 21_3 with respect to the X direction. The opening direction of the second damper 21_2 with respect to the Y direction is set to the positive direction. The opening direction of the third damper 21_3 with respect to the Y direction is set to the negative direction. Therefore, as illustrated in FIG. 7A, the connector 11 is guided to a position near the arrangement position of the terminal 12 by the wiring work performed by the worker. That is, the connector 11 is guided to a position suitable for connection work. Accordingly, handling of the cable 7 in the connection work can be facilitated.

Secondly, as shown in FIG. 3, the third damper 21_3 is disposed inside the virtual circle C2. As illustrated in FIG. 7C, when the extra length processing is performed, the cable 7 rotates about the connector 11 (see D5 in the drawing), and the cable 7 moves in the direction orthogonal to the longitudinal direction of the third damper 21_3 (see D3 in the drawing). Here, since the cable 7 is fixed at the second damper 21_2 after the movement, a force in the negative direction in the Y direction is generated in the cable 7 at the third damper 21_3. This makes it possible to suppress the occurrence of return of the cable 7. As a result, it is possible to avoid the shape of the first half portion of the cable 7 from returning from the shape illustrated in FIG. 7D to the shape illustrated in FIG. 7C.

Thirdly, as shown in FIG. 3, the arrangement position of the first damper 21_1 with respect to the X direction is set at a position between the arrangement position of the terminal 12 with respect to the X direction and the arrangement position of the second damper 21_2 with respect to the X direction. The opening direction of the first damper 21_1 with respect to the Y direction is set to be opposite to the opening direction of the second damper 21_2 with respect to the Y direction. Since the first damper 21_1 is provided in addition to the second damper 21_2, the orientation of the cable 7 between the pull-out portion 13 and the second damper 21_2 can be stabilized.

In addition, since the third clamper 21_3 is provided in addition to the first damper 21_1 and the second clamper 21_2, as illustrated in FIG. 7C, the movable direction of the cable 7 in the extra length processing can be limited to a predetermined direction (see D2, D3, and D4 in the drawing). Further, the movable range of the cable 7 in the extra length processing can be limited to a predetermined range (see R1 and R2 in the drawing).

Fourthly, the opening direction of the first damper 21_1 with respect to the X direction is set to the negative direction, and the opening direction of the second damper 21_2 with respect to the Y direction is set to the negative direction. That is, the opening direction of the first damper 21_1 is set to a direction inclined with respect to each of the X direction and the Y direction. As a result, it is possible to improve the workability of the work in which the worker hooks the cable 7 on the first clamper 21_1 and the work in which the worker hooks the cable 7 on the second damper 21_2. As a result, the mechanical load applied to the cable 7 by these works can be reduced. In addition, the behavior of the cable 7 when the cable 7 is clamped by the second damper 21_2 can be stabilized.

Fifth, the chassis 4 is provided with the protrusion 22 having a drawing shape. As shown in FIG. 3, the protrusion 22 is disposed between the first damper 21_1 and the second clamper 21_2. Therefore, in addition to the cable 7 being held due to clamping by the first damper 21_1 and the second damper 21_2, the cable 7 is held by the contact with the protrusion 22. This makes it possible to stabilize the behavior of the cable 7 when the cable 7 is clamped by the second damper 21_2 in the wiring work. In addition, when the cable 7 is pushed in by the extra length processing, the cable 7 can be hardly detached from the second damper 21_2.

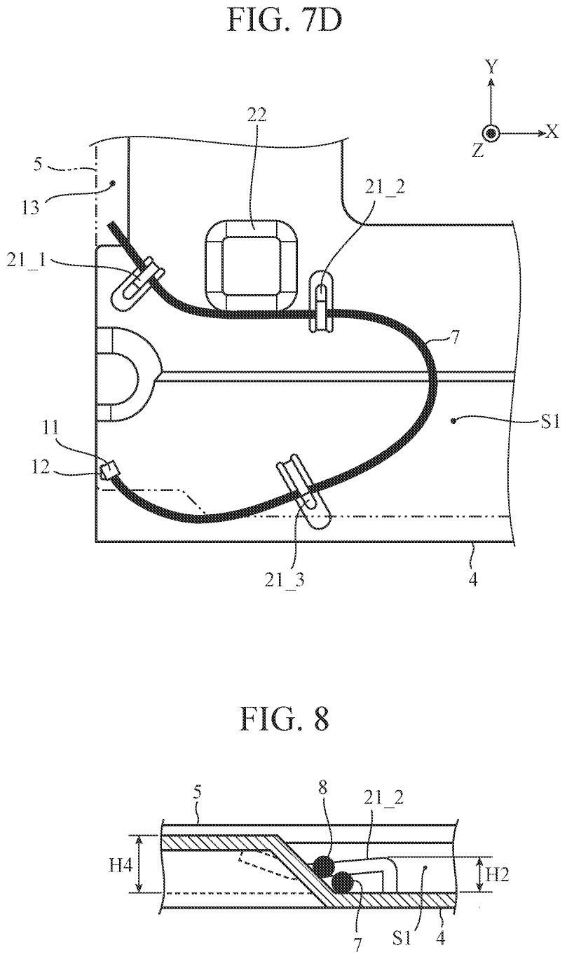

Sixth, as shown in FIGS. 5 and 6, the height H4 of the protrusion 22 is set to a value larger than that of the height H2 of the second clamper 21_2. As a result, for example, in a case where the liquid crystal module 3 and the substrate 5 are electrically connected by a plurality of cables including the cable 7 and the other cable 8, and the plurality of cables is clamped by the plurality of dampers 21, when the plurality of cables is arranged side by side in the Z direction between the first damper 21_1 and the second damper 21_2 (see FIG. 8), the plurality of cables can be brought into contact with the protrusion 22. As a result, the plurality of cables can be held.

Seventh, the height H3 (see FIG. 4) of the third damper 21_3 is set to a value larger than those of the height H1 (not shown) of the first damper 21_1 and the height H2 (see FIGS. 5 and 6) of the second damper 21_2. Therefore, as described above, the cable 7 is fixedly clamped by the first damper 21_1 and the second damper 21_2, and is movably clamped by the third damper 21_3.

As a result, a plurality of functions can be implemented using the plurality of dampers 21. That is, the first clamper 21_1 and the second damper 21_2 mainly function to fix the cable 7 to the chassis 4. On the other hand, the third damper 21_3 mainly functions to guide the connector 11 to a position suitable for the connection work (that is, a position near the terminal 12) at the time of the wiring work, and functions to limit the movable direction and the movable range of the cable 7 in the extra length processing.

Next, a modification of the electronic apparatus 100 will be described.

The number of dampers 21, the arrangement positions of the individual dampers 21, the opening directions of the individual dampers 21, and the heights of the individual dampers 21 are not limited to the examples illustrated in FIGS. 3 to 6 and the like. In addition, the arrangement position of the protrusion 22, the height H4 of the protrusion 22, and the presence or absence of the protrusion 22 are not limited to the examples illustrated in FIGS. 3 to 6 and the like. In addition, the arrangement position of the terminal 12 and the arrangement position of the pull-out portion 13 are not limited to the examples illustrated in FIGS. 3 to 6 and the like.

These parameters may be set so as to implement at least a function of fixing the cable 7 to the chassis 4, a function of limiting the movable direction of the cable 7 in the extra length processing to a predetermined direction, and a function of limiting the movable range of the cable 7 in the extra length processing to a predetermined range. More preferably, these parameters may be set so as to implement, in addition to these functions, a function of suppressing the return of the cable 7 after the extra length processing and a function of guiding the connector 11 to a position suitable for the connection work (that is, a position near the arrangement position of the terminal 12) by the wiring work.

That is, specific aspects of these parameters for implementing these functions can vary depending on the application, specification, and the like of the electronic apparatus 100. Therefore, these parameters only need to be set by those skilled in the art so that these functions are implemented in accordance with the application, specification, and the like of the electronic apparatus 100.

For example, the plurality of dampers 21 may include a fourth damper 21_4 (not illustrated) in addition to the first damper 21_1, the second damper 21_2, and the third clamper 21_3. The fourth damper 21_4 is formed on the chassis 4 instead of the protrusion 22. The fourth damper 21_4 fixedly holds the cable 7.

Further, for example, the second damper 21_2 may include two or more dampers. That is, the plurality of dampers 21 may include four or more dampers, and the cable 7 may be fixed by three or more dampers among the four or more dampers.

Further, for example, the terminal 12 and the pull-out portion 13 may be arranged at a center portion of the chassis 4 instead of being arranged at an edge portion of the chassis 4 (more specifically, one short side portion of two short side portions).

In addition, the connection portion between the connector 11 and the terminal 12 may be configured to be non-rotatable. However, as described above, from the viewpoint of reducing the mechanical load applied to the first end portion of the cable 7, the connection portion between the connector 11 and the terminal 12 is more preferably configured to be rotatable.

In addition, the application of the electronic apparatus 100 is not limited to the display device for the in-vehicle information device. The electronic apparatus 100 may be used for any electronic apparatus as long as it is an electronic apparatus including at least the chassis 4, the substrate 5, and the cable 7.

As described above, the electronic apparatus 100 according to the first embodiment includes the chassis 4 and the substrate 5 arranged to face each other, the cable 7 disposed between the chassis 4 and the substrate 5 and having an extra length, and the plurality of dampers 21 formed on the chassis 4 and clamping the cable 7. The plurality of dampers 21 includes the second damper 21_2 fixedly clamping the cable 7 and the third damper 21_3 movably clamping the cable 7. The cable 7 is fixed to the chassis 4 by the second damper 21_2, and the movable direction and the movable range of the cable 7 in the extra length processing of the cable 7 are limited by the third damper 21_3. As a result, the electronic apparatus 100 having a structure for extra length processing can be achieved. In addition, an additional member such as a hook-and-loop fastener can be made unnecessary in fixing the cable 7 to the chassis 4. As a result, it is possible to avoid an increase in the number of components of the electronic apparatus 100 due to such an additional member.

In addition, the plurality of dampers 21 suppresses the return of the cable 7 after the extra length processing. As a result, for example, it is possible to avoid the shape of the cable 7 from returning from the shape illustrated in FIG. 7D to the shape illustrated in FIG. 7C after the extra length processing is performed. In other words, after the extra length processing is performed, the shape of the first half portion of the cable 7 can be maintained in a substantially U shape.

Further, the electronic apparatus 100 includes the connector 11 provided at the first end portion of the cable 7 and the terminal 12 provided on the substrate 5 and connected with the connector 11. The arrangement position of the second damper 21_2 with respect to the first direction (X direction) of the first direction (X direction) and the second direction (Y direction) orthogonal to each other among the directions along the plate surface of the chassis 4 is set at a position different from the arrangement position of the terminal 12 with respect to the first direction (X direction), and is set at a position equivalent to the arrangement position of the third damper 21_3 with respect to the first direction (X direction). The opening direction of the second damper 21_2 with respect to the second direction (Y direction) is set to the positive direction, and the opening direction of the third damper 21_3 with respect to the second direction (Y direction) is set to the negative direction. As a result, when the worker performs the wiring work, the connector 11 is guided to a position near the arrangement position of the terminal 12. That is, the connector 11 is guided to a position suitable for connection work. As a result, handling of the cable 7 in the connection work can be facilitated.

In addition, the third damper 21_3 is disposed inside the predetermined circle C2, and the predetermined circle C2 is a circle C2 that passes through a position corresponding to the arrangement position of the second damper 21_2, passes through a position corresponding to the arrangement position of the terminal 12, and has a circumferential length corresponding to the wiring length L of the cable 7. This makes it possible to suppress the occurrence of return of the cable 7.

The plurality of dampers 21 includes the first clamper 21_1 that fixedly clamps the cable 7, and the cable 7 is fixed to the chassis 4 by the first damper 21_1 and the second damper 21_2. The arrangement position of the first damper 21_1 with respect to the first direction (X direction) is set at a position between the arrangement position of the terminal 12 with respect to the first direction (X direction), and the arrangement position of the second damper 21_2 with respect to the first direction (X direction). The opening direction of the first damper 21_1 with respect to the second direction (Y direction) is set to a direction opposite to the opening direction of the second damper with respect to the second direction (Y direction). This makes it possible to stabilize the orientation of the cable 7 between the pull-out portion 13 and the second clamper 21_2. In addition, the movable direction of the cable 7 in the extra length processing can be limited to a predetermined direction, and the movable range of the cable 7 in the extra length processing can be limited to a predetermined range.

Further, the opening direction of the first damper 21_1 with respect to the first direction (X direction) is set to the negative direction, and the opening direction of the first damper 21_1 with respect to the second direction (Y direction) is set to the negative direction. As a result, it is possible to improve the workability of the work in which the worker hooks the cable 7 on the first damper 21_1 and the work in which the worker hooks the cable 7 on the second damper 21_2. As a result, the mechanical load applied to the cable 7 by these works can be reduced. In addition, the behavior of the cable 7 when the cable 7 is clamped by the second clamper 21_2 can be stabilized.

In addition, the electronic apparatus 100 includes the protrusion 22 provided on the chassis 4 and having a drawing shape, and the protrusion 22 is disposed between the first damper 21_1 and the second clamper 21_2. This makes it possible to stabilize the behavior of the cable 7 when the cable 7 is clamped by the second damper 21_2 in the wiring work. In addition, when the cable 7 is pushed in by the extra length processing, the cable 7 can be hardly detached from the second damper 21_2.

The height H4 of the protrusion 22 is set to a value larger than that of the height H2 of the second damper 21_2. As a result, when a plurality of cables including the cable 7 and the other cable 8 is arranged side by side in the Z direction between the first damper 21_1 and the second damper 21_2, the plurality of cables can be held.

The height H3 of the third damper 21_3 is set to a value larger than that of the height H2 of the second damper 21_2. As a result, the second damper 21_2 that fixedly clamps the cable 7 can be achieved, and the third damper 21_3 that movably clamps the cable 7 can be achieved. The third damper 21_3 can implement a function of limiting the movable direction and the movable range of the cable 7 in the extra length processing.

In addition, the connection portion between the connector 11 and the terminal 12 is configured to be rotatable. When the cable 7 is pushed in by the extra length processing, the connector 11 rotates with respect to the terminal 12, so that a mechanical load applied to the first end portion of the cable 7 can be reduced.

It should be noted that the invention of the present application is capable of modifying any of the constituent elements of the embodiment or omitting any of the constituent elements of the embodiment within the scope of the invention.

### INDUSTRIAL APPLICABILITY

The electronic apparatus of the present invention can be used for, for example, a display device for an in-vehicle information device.

### REFERENCE SIGNS LIST

1: front panel, 2: rear cover, 3: liquid crystal module, 4: chassis, 5: substrate, 6: flat cable, 7: cable, 8: cable, 11: connector, 12: terminal, 13: pull-out portion, 21: damper, 21_1: first damper, 21_2: second damper, 21_3: third damper, 22: protrusion, 100: electronic apparatus

1. An electronic apparatus, comprising:
a chassis and a substrate arranged to face each other;
a cable disposed between the chassis and the substrate and having an extra length; and
a plurality of dampers formed on the chassis and clamping the cable, wherein
the plurality of dampers includes a second clamper fixedly clamping the cable and a third damper movably clamping the cable,
the cable is fixed to the chassis by the second damper, and
the third damper limits a movable direction and a movable range of the cable in extra length processing of the cable.

2. The electronic apparatus according to claim 1, wherein return of the cable after the extra length processing is suppressed by the plurality of dampers.

3. The electronic apparatus according to claim 1, further comprising:
a connector provided at a first end portion of the cable; and
a terminal provided on the substrate and connected with the connector,
wherein an arrangement position of the second damper with respect to a first direction, out of the first direction and a second direction orthogonal to each other among directions along a plate surface of the chassis, is set at a position different from an arrangement position of the terminal with respect to the first direction, and is set at a position equivalent to an arrangement position of the third damper with respect to the first direction,
an opening direction of the second damper with respect to the second direction is set to a positive direction, and
an opening direction of the third clamper with respect to the second direction is set to a negative direction.

4. The electronic apparatus according to claim 3, wherein
the third damper is disposed inside a predetermined circle, and
the predetermined circle is a circle that passes through a position corresponding to the arrangement position of the second damper, passes through a position corresponding to the arrangement position of the terminal, and has a circumferential length corresponding to a wiring length of the cable.

5. The electronic apparatus according to claim 3, wherein
the plurality of dampers includes a first damper fixedly clamping the cable,
the cable is fixed to the chassis by the first damper and the second clamper,
an arrangement position of the first damper with respect to the first direction is set at a position between the arrangement position of the terminal with respect to the first direction and the arrangement position of the second damper with respect to the first direction, and
an opening direction of the first damper with respect to the second direction is set to a direction opposite to the opening direction of the second clamper with respect to the second direction.

6. The electronic apparatus according to claim 5, wherein
an opening direction of the first damper with respect to the first direction is set to a negative direction, and
the opening direction of the first damper with respect to the second direction is set to a negative direction.

7. The electronic apparatus according to claim 3, wherein a height of the third damper is set to a value larger than that of a height of the second damper.

8. The electronic apparatus according to claim 5, further comprising a protrusion having a drawing shape formed on the chassis, wherein
the protrusion is disposed between the first damper and the second damper.

9. The electronic apparatus according to claim 8, wherein a height of the protrusion is set to a value larger than that of a height of the second damper.

10. The electronic apparatus according to claim 3, wherein a connection portion between the connector and the terminal is configured to be rotatable.
